(19) United States
(12) Patent Application Publication
(10) Pub. No.: US 2007/0279847 A1
(43) Pub. Date: Dec. 6, 2007

(54) Electronic device having a slidable cover that slides via a rack

(75) Inventors: Hsiao-Feng Li, Taipei City (TW); Po-Jen Ke, Taipei City (TW)

Correspondence Address: BIRCH, STEWART, KOLASCH & BIRCH, LLP, 8110 GATEHOUSE ROAD, SUITE 100 EAST, FALLS CHURCH, VA, 22315, US

(73) Assignee: ASUSTeK COMPUTER INC.

(21) Appl. No.: 11/797,301

(22) Filed: May 2, 2007

(30) Foreign Application Priority Data
May 3, 2006 (TW) 095115713

(51) Int. Cl. H05K 5/02

(52) U.S. Cl. 361/679

(57) ABSTRACT

A first housing of an electronic device is connected to a second housing of the electronic device in a slidable manner. A rack is positioned on the first housing. A gear unit and a hinge are positioned on the second housing. The gear unit engages with the rack, and a gear positioned at an end of the hinge engages with the gear unit.

### BACKGROUND OF THE INVENTION

1. Field of the Invention

The present invention provides an electronic device having a slidable cover, in particular an electronic device having a slidable cover that slides via a rack.

2. Description of the Prior Art

Please refer to FIG. 1 to FIG. 4. FIG. 1 to FIG. 4 present a sliding structure 1 inside a cellphone having a slidable cover in the prior art. The sliding structure 1 comprises a main board 10, a moving board 12 and a torsional spring 14. The torsional spring 14 comprises four connecting points with two of the connecting points placed on fixing points 11, 13 on the main board 10 and the other two connecting points placed on fixing points 15, 17 on the moving board 12. The main board 10 comprises two rails 16 and the moving board 12 also comprises two rails 18 (as in FIG. 4) that are used to connect with the rails 16 of the main board 10.

As the sliding structure 1 is in a situation shown in FIG. 1, the elastic potential energy of the torsional spring 14 is fully released. If a force is applied to the moving board 12, the torsional spring 14 is compressed. When the torsional spring 14 is compressed to a maximum, as displayed in FIG. 2, the torsional spring stores a maximum elastic potential energy. With a conversion from the elastic potential energy to kinetic energy, the moving board 12 can move to another side of the main board 10, as shown in FIG. 3.

The prior art uses a torque of the torsional spring to move a sliding cover of a cellphone. However, the sliding structure 1 in FIG. 1 needs a large area when realized in a cellphone and cellphone design therefore needs to be compromised because the prior art cannot agree with a trend of cellphones getting smaller and smaller.

### SUMMARY OF THE INVENTION

An electronic device having a sliding cover is disclosed. The electronic device comprises a first housing, a second housing, a rack disposed on the first housing, and a hinge disposed on the second housing. An end of the hinge is connected to a first gear, which meshes with the rack. The hinge comprises a first cam coupled to the first gear, a second cam disposed under the first cam and connected to the first cam, and an elastic component disposed under the second cam. When the second housing slides along a first direction due to a push force corresponding to the first housing, the first cam is caused to rotate along a first rotational direction in relation to the second cam with the elastic component providing an elastic force to the second cam so that as the push force vanishes, the first cam rotates along a direction that is the same as the first rotational direction in relation to the second cam.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 present a sliding structure inside a cellphone having a slidable cover in the prior art.

FIG. 5 is an exploded diagram of a sliding structure that is an embodiment of the present invention.

FIG. 6 is a diagram combining components of the sliding structure in FIG. 5.

FIG. 7 and FIG. 8 are diagrams of motions of the sliding structure.

FIG. 9 and FIG. 10 are diagrams of the sliding structure realized as an electronic device having a sliding cover.

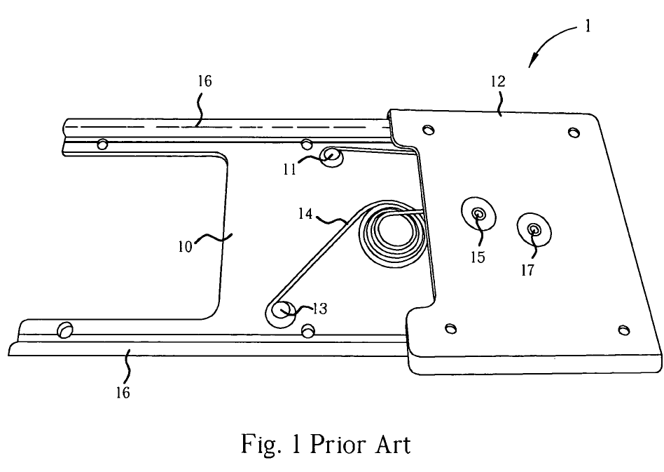

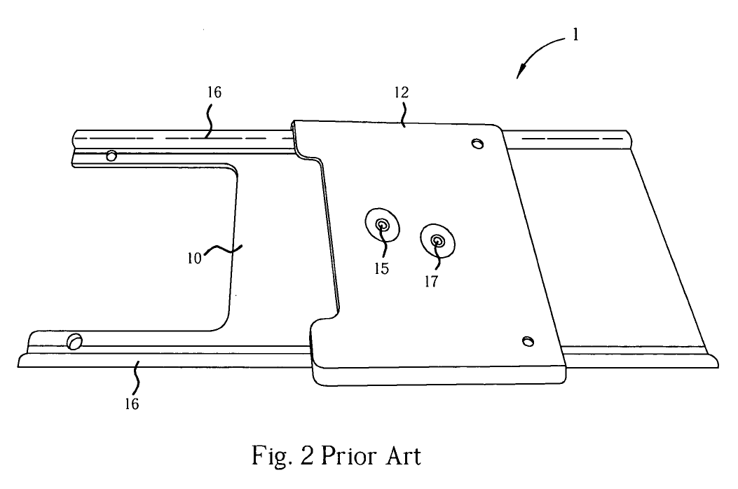

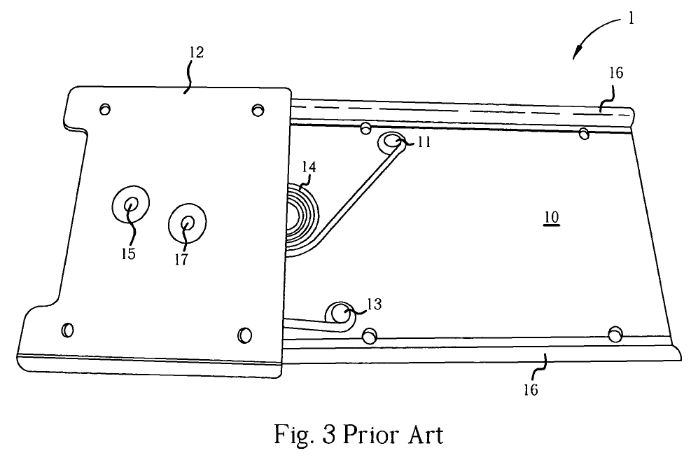

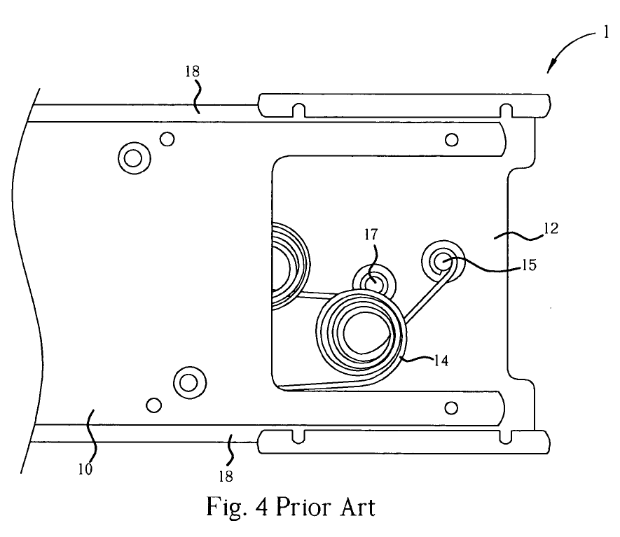

### DETAILED DESCRIPTION

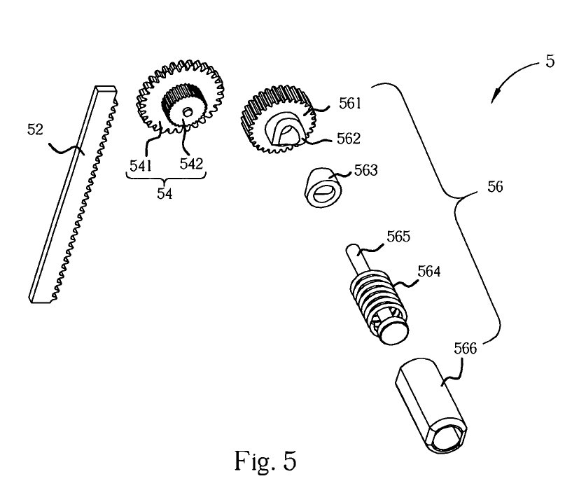

Please refer to FIG. 5. FIG. 5 is an exploded diagram of a sliding structure 5 that is an embodiment of the present invention. The sliding structure 5 comprises a rack 52, a gear unit 54 and a hinge 56. The hinge comprises a first gear 561, a first cam 562, a second cam 563, a spring 564, a bolt 565 and a housing 566. The gear unit 54 comprises a second gear 541 and a third gear 542 where the second gear 541 and the third gear 542 share a same axis.

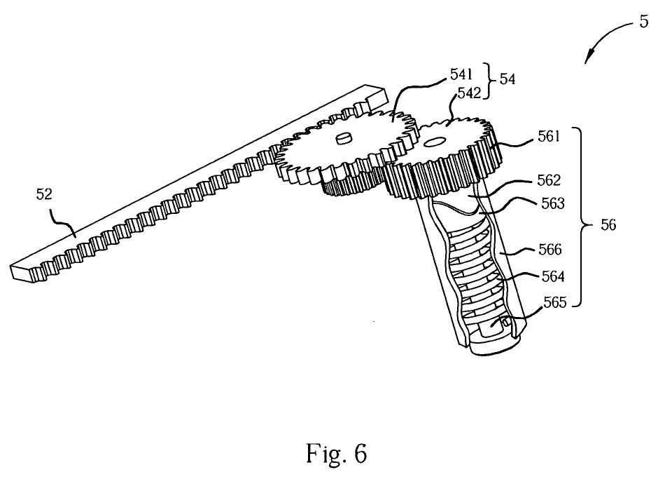

Please refer to FIG. 6. FIG. 6 is a diagram combining components of the sliding structure 5 in FIG. 5. The first cam 562, the second cam 563, the spring 564 and the bolt 565 are placed inside the housing 566. The bolt 565 is placed inside the spring 564; the second cam 563 slides along the bolt 565 through a link with the first cam 562. With the sliding of the second cam 563 the spring 564 is compressed. The rack 52 meshes with the second gear 541 of the gear unit 54, and the first gear 561 of the hinge 56 meshes with the third gear 542 of the gear unit 54.

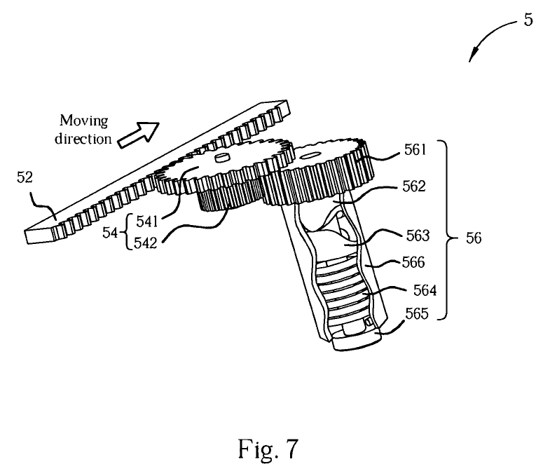

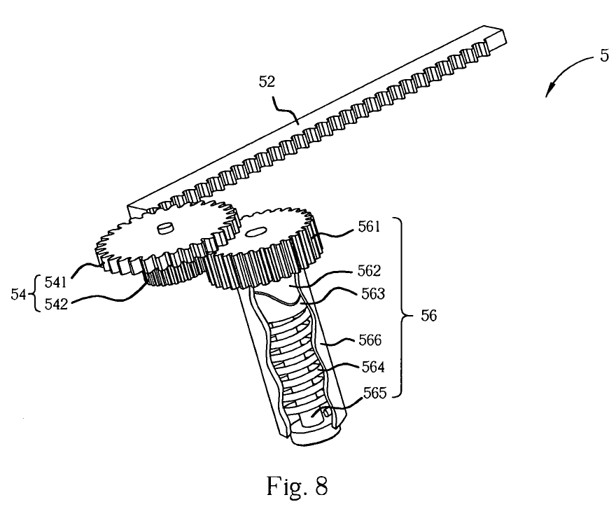

FIG. 7 and FIG. 8 are diagrams of motions of the sliding structure 5. When the rack 52 moves, which drives the gear unit 54 to rotate, and the first gear 561 of the hinge 56 rotates. Since the first cam 562 shares the same axis as the first gear 561, the first cam 562 and the second cam 563 starts rotating. While rotating, the second cam slides downwards and compresses the spring 564 (as in FIG. 7).

When in a situation as shown in FIG. 7, removing the force on the rack 52 allows using the hinge 56 to drive the gear unit 54 to rotate and the rack 52 to move. With a rebound of the spring 564, the second cam 563 slides upwards and continues to rotate in correspondence to the first cam 562. The first cam 562 continues to rotate and drives the gear unit 54 to rotate, hence moving the rack 52. When the spring 564 recovers to its original length, all the rotating and moving stops, as shown in FIG. 8.

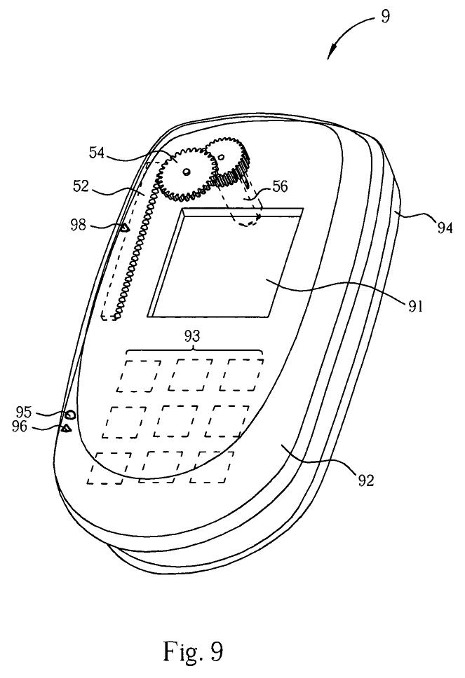

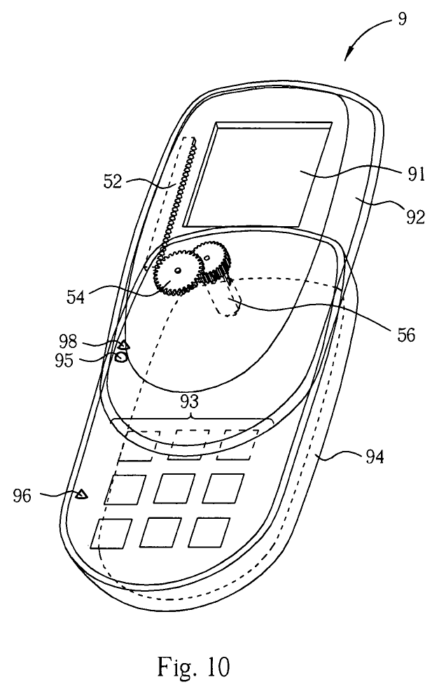

Please refer to FIG. 9 and FIG. 10. FIG. 9 and FIG. 10 are diagrams of the sliding structure 5 realized as an electronic device having a sliding cover 9. The electronic device having a sliding cover 9 comprises a first housing 92 and a second housing 94. The first housing 92 comprises a display monitor 91, and inside the first housing 92 is a first fixing component 95. Inside the second housing 94 is a second fixing component 96 and a third fixing component 98. The rack 62 of the sliding structure 5 is placed on the first housing 92, while the gear unit 54 and the hinge 56 are placed on the second housing 94.

The first fixing component 95 of the first housing 92 in FIG. 9 detachably connects with the second fixing component 96 of the second housing 94 to fix relative locations of the first housing 92 and the second housing 94. After completing the motion of the sliding structure 5, as in FIG. 10, the first fixing component 95 of the first housing 92 detachably connects and fixes with the third fixing component 98 of the second housing 94 to fix final relative locations of the first housing 92 and the second housing 94 after the first housing has been fully extended.

The sliding structure of the embodiment of the present invention does not occupy a large area and an overall length can be adjusted with different matching springs, so that a thickness of an electronic device occupied by the sliding structure can be altered according to design requirements. Therefore design of the electronic device can be decreased, agreeing with a current trend.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device having a sliding cover, the electronic device comprising:
a first housing;
a second housing;
a rack disposed on the first housing; and
a hinge disposed on the second housing, an end of the hinge connected to a first gear which meshes with the rack, the hinge comprising:
a first cam coupled to the first gear;
a second cam disposed under the first cam and connected to the first cam; and
an elastic component, disposed under the second cam;
wherein when the second housing slides along a first direction due to a push force corresponding to the first housing, the first cam is caused to rotate along a first rotational direction in relation to the second cam, the elastic component providing an elastic force to the second cam so that as the push force vanishes, the first cam rotates along a direction that is the same as the first rotational direction in relation to the second cam.

2. The electronic device having a sliding cover of claim 1 wherein the elastic component is a spring.

3. The electronic device having a sliding cover of claim 1 wherein the hinge comprises a bolt that is placed inside the elastic component.

4. The electronic device having a sliding cover of claim 3 wherein the hinge further comprises a housing, and the first cam, the second cam, the elastic component and the bolt are disposed in the housing.

5. The electronic device having a sliding cover of claim 1 wherein a first fixing component is disposed on the first housing, a second fixing component is disposed on the second housing for fixing with the first fixing component so that the first housing and the second housing are fixed at corresponding locations.

6. A electronic device having a sliding cover, the electronic device comprising:
a first housing;
a second housing;
a rack disposed on the first housing;
a hinge disposed on the second housing, an end of the hinge connected to a first gear, the hinge comprising:
a first cam coupled to the first gear;
a second cam disposed under the first cam and connected with the first cam; and
an elastic component disposed under the second cam; and
a gear set disposed inside the second housing and meshes with the rack and the first gear of the hinge;
wherein when the second housing slides along a first direction due to a push force corresponding to the first housing, the first cam is caused to rotate along a first rotational direction in relation to the second cam, the elastic component providing an elastic force to the second cam so that as the push force vanishes, the first cam rotates along a direction that is the same as the first rotational direction in relation to the second cam.

7. The electronic device having a sliding cover of claim 6 wherein the gear set comprises a second gear meshed with the rack and a third gear meshed with the first gear of the hinge.

8. The electronic device having a sliding cover of claim 7 wherein the second gear and the third gear share a same axis.

9. The electronic device having a sliding cover of claim 6 wherein the elastic component is a spring.

10. The electronic device having a sliding cover of claim 6 wherein the hinge comprises a bolt that is placed inside the elastic component.

11. The electronic device having a sliding cover of claim 10 wherein the hinge further comprises a housing, and the first cam, the second cam, the elastic component and the bolt are placed in the housing.

12. The electronic device having a sliding cover of claim 6 wherein a first fixing component is placed on the first housing, a second fixing component is placed on the second housing for fixing with the first fixing component so that the first housing and the second housing are fixed at corresponding locations.
